(19) United States
(12) Patent Application Publication
(10) Pub. No.: US 2010/0243046 A1
(43) Pub. Date: Sep. 30, 2010

(54) METHOD OF FORMING A PROTECTIVE LAYER ON THIN-FILM PHOTOVOLTAIC ARTICLES AND ARTICLES MADE WITH SUCH A LAYER

(76) Inventors: Marty W. Degroot, Midland, MI (US); Rebekah K. Feist, Midland, MI (US); Mark T. Bernius, Midland, MI (US); William F. Banholzer, Freeland, MI (US); Chung-Hei Yeung, Midland, MI (US); Attiganal N. Sreeram, Midland, MI (US); Robert P. Haley, JR., Midland, MI (US)

Correspondence Address: The Dow Chemical Company, P.O. BOX 1967, Midland, MI, 48641, US

(21) Appl. No.: 12/729,547

(22) Filed: Mar. 23, 2010

Related U.S. Application Data
(60) Provisional application No. 61/163,101, filed on Mar. 25, 2009.

(51) Int. Cl. H01L 31/0216; H01L 31/18

(52) U.S. Cl. 136/256; 438/80; 257/E31.119

(57) ABSTRACT

Chalcogenide based photovoltaic devices cells with good resistance to environmental elements can be formed by direct low temperature deposition of inorganic barrier layers onto the film. A unique multilayer barrier can be formed in a single step when reactive sputtering of the silicon nitride onto an inorganic oxide top layer of the PV device.

### CROSS-REFERENCE TO RELATED APPLICATION(S)

This application claims benefit of priority from U.S. Provisional Patent Application No. 61/163,101, filed Mar. 25, 2009, which application is incorporated by reference herein in its entirety.

### FIELD OF THE INVENTION

The invention disclosed herein relates generally to the field of thin-film photovoltaics and methods of forming protective layers on such photovoltaic devices.

### BACKGROUND OF THE INVENTION

Non-polluting sources of energy are actively being sought as a replacement for the burning of fossil fuels. The generation of energy from solar radiation is one type of clean energy that is receiving significant attention. Solar energy collectors, such as photovoltaic cells (also referred to as “solar cells”), may be used to generate energy where and when there is adequate sunlight. While silicon based solar cells are prevalent, they suffer from certain disadvantages. For example, the silicon based solar panels tend to be relatively large and heavy and are not flexible.

In recent years, technologies relating to thin-film solar cells have advanced to overcome such characteristics exhibited by the silicon-based solar cells to afford a lighter weight product with a more flexible form factor. As such, solar cells based on IB-IIIB-chalcogenides have been proposed as a thin film alternative to silicon based cells. Since photovoltaic articles are frequently located outdoors, considerable efforts have been devoted to designing thin-film photovoltaic cells that are sufficiently robust against environmental conditions while maintaining flexibility and achieving high efficiencies. Various types of protective layers have been proposed for use with such chalcogenide based cells.

US 2008/0139003 (Pirzada et al) teaches use of a PECVD deposition of SiNₓ, SiO₂, SiC or the like for solar cell passivation at high deposition rates at temperatures less than 150° C. by a plasma enhanced chemical vapor deposition. Pirzada et al further teach that silicon nitride is a good insulating material on thin film solar cells, that silicon nitride is known for its barrier properties and that silicon nitride is deposited either by reactive sputtering or PECVD. Pirzada et al teach that the PECVD technique is more attractive due to its high deposition rate and better conformality of deposition. However, Pirzada teaches that for passivation of silicon based thin film solar panels the barrier coating must be applied at <150° C. to avoid degradation of semiconductor films previously deposited on the substrate. However, low temperatures lead to undesirable particulate formation on the final product, which would lead to the user to avoid such a technique. Pirzada does not discuss chalcogenide based photovoltaic devices.

Glick et al. (Silicon Oxynitride Thin Film Barriers for PV Packaging, Conference Paper NREL/CP-520-38959, November 2005) also investigated applying silicon oxynitride films as barriers for photovoltaic devices using a low temperature PECVD method. However, Glick reported water vapor transmission rates (WVTR) of 0.2, 0.5 and 13.45 g/m²/day at about 38, 59, and 85° C. and 100% relative humidity. These WVTR were acknowledged as being insufficient to provide adequate protection for PV devices.

### SUMMARY OF THE INVENTION

Surprisingly, the present inventors have discovered that inorganic barrier films (preferably silicon nitride) can be applied to chalcogenide based PV devices at low temperatures to provide good barrier properties. Specifically, the applicants have discovered that chalcogenide cells with improved resistance to environmental elements can be formed by direct low temperature deposition of inorganic barrier layers onto the cell but such layers cannot be formed using standard chemical vapor deposition methods to provide the barrier layer. Moreover, applicants have discovered that a unique multilayer barrier can be formed in a single step when reactive sputtering of the silicon nitride onto an inorganic oxide top layer of the PV device.

Thus, according to a first embodiment the invention is a method of forming a photovoltaic article comprising:

providing at least one chalcogenide based photovoltaic cell

direct depositing an inorganic barrier layer onto the at least one chalcogenide based photovoltaic cell at a temperature of less than 200° C. wherein the resulting photovoltaic article retains at least 85% of its efficiency after exposure of at least 1000 hours to 85° C. and 85% relative humidity.

According to a second embodiment the invention is a method of forming a photovoltaic article comprising: providing at least one chalcogenide based photovoltaic cell and magnetron sputtering onto the at least one cell an inorganic barrier layer (preferably a silicon nitride layer). According to one preferred embodiment, barrier layer is a silicon nitride and the layer it is sputtered onto is an inorganic oxide and simultaneously with forming the silicon nitride barrier and silicon oxynitride sublayer is formed.

According to a third embodiment the invention is an article formed by the methods of the first and second embodiments.

### BRIEF DESCRIPTION OF THE DRAWINGS

FIG. 1 is a schematic of an exemplary photovoltaic cell having a silicon nitride protective layer.

FIG. 2 is an SEM of a substrate showing an interfacial layer between an inorganic oxide and a reactive sputtered silicon nitride.

### DETAILED DESCRIPTION OF THE INVENTION

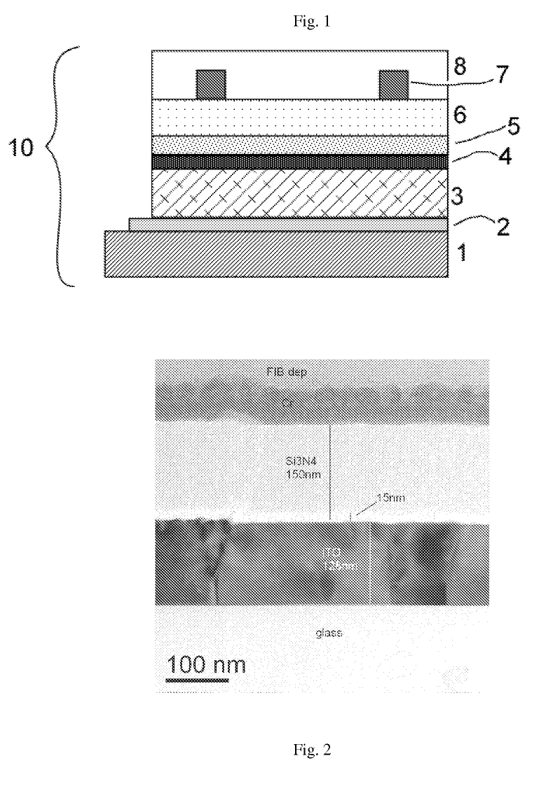

Referring to FIG. 1, one embodiment of the photovoltaic article 10 of this invention is shown. This article 10 comprises a substrate 1, a backside electrical contact 2, a chalcogenide absorber 3, a buffer layer 4, an optional front side electrical contact window layer 5, a transparent conductive oxide layer 6 that may also include a collection grid 7, and a reactively sputtered silicon nitride protective layer 8. Note that substrate 1 and backside electrical contact 2 may alternatively be a single component such as a metal foil. Additional layers standard in photovoltaic cells may also be provided. As used occasionally herein, the top of the cell is that side which receives the sunlight, namely the side containing the grid and topcoat.

The substrate 1 may be a rigid or flexible substrate. Examples of suitable substrates include but are not limited to glass, polymer, ceramic, metal, and combinations thereof. Preferably, however, the substrate is flexible and is either stainless steel or titanium.

The backside electrical contact 2 may be molybdenum, tungsten, tantalum, and niobium, but is preferably molybdenum. This may be applied to the substrate by sputtering or as noted above, this layer may serve as both the substrate and the backside electrical contact in which case a separate substrate 1 is not included.

The chalcogenide absorber 3 is preferably a layer of IB-IIIB-chalcogenide, such as IB-IIIB-selenides, IB-IIIB-sulfides, and IB-IIIB-selenides-sulfides. More specific examples include copper indium selenides, copper indium gallium selenides, copper gallium selenides, copper indium sulfides, copper indium gallium sulfides, copper gallium selenides, copper indium sulfide selenides, copper gallium sulfide selenides, and copper indium gallium sulfide selenides (all of which are referred to herein as CIGSS). These can also be represented by the formula CuIn₍₁₋ₓ₎GaₓSe_{(2-y)}S_{y} where x is 0 to 1 and y is 0 to 2. The copper indium selenides and copper indium gallium selenides are preferred. This layer may be formed by known methods onto substrate 1 and electrical contact 2. The absorber layer may be deposited or grown using a variety of techniques such as evaporation, sputtering, electrodeposition, spraying, and sintering. One preferred method is co-evaporation of the constituent elements, where the individual constituent elements are thermally evaporated on a hot surface coincidentally and at the same time to form the compound semiconductor absorber layer.

The buffer layer 4 is preferably an n-type material such as sulfides, selenides, and oxides of Cd, Zn, In, Sn and combinations thereof. A most preferred buffer layer 4 is CdS. This layer can be formed on the absorber layer 3 by any known method, such as for example chemical bath deposition, partial electrolyte treatment, evaporation, or sputtering.

The front side electrical contact layer 5 and the transparent conductive oxide (TCO) layer 6 is situated above the n-type buffer layer in a typical embodiment. The layer 5 is preferred but not required. It is typically called a window layer, and it may serve to protect the device from shunts and can protect the buffer layer during deposition of the transparent conductive oxide. The window layer is typically a resistive transparent oxide such as an oxide of Zn, In, Cd, Sn, but is preferably intrinsic ZnO. Suitable TCO secondary layers, or equally suitable material candidates for employing the single compound layer, include fluorine-doped tin oxide, tin oxide, indium oxide, indium tin oxide (ITO), aluminum zinc oxide (AZO) and zinc oxide. Preferably the TCO is a bilayer of zinc oxide and a second layer of either ITO or AZO. This bilayer may be formed for example by sputtering.

The optional electron grid collection structure 7 may be deposited over the TCO layer to reduce the sheet resistance of this layer. The grid layer is preferably composed of Ag, Al, Cu, Cr, Ni, Ti, Taand combinations thereof. Preferably the grid is made of Ag. This layer can be made of a wire mesh or similar wire structure, it can be formed by screen-printing, ink-jet printing, electroplation, and metallization thru a shadow mask using physical vapor deposition techniques such as evaporation or sputtering.

According to the method of this invention, a chalcogenide based photovoltaic cell is rendered less susceptible to moisture related degradation via direct, low temperature application of an inorganic barrier layer to the top layer of the photovoltaic device. The barrier material can be selected from a group of metal oxides, nitrides and carbides or combinations and alloys thereof. The inorganic barrier layer preferably comprises silicon nitride and/or silicon oxynitride (e.g. exhibiting the formula SiO_{y}N_{z} where according to one preferred embodiment y is 0, according to another preferred embodiment, y is greater than 0.0, more preferably greater than 0.1 and preferably less than 0.8, more preferably less than 0.5, more preferably still less than 0.3, yet more preferably less than 0.2 and according to one preferred less than 0.05; and z is preferably greater than 0.8, more preferably greater than 1.0, and more preferably greater than 1.1, and preferably less than 1.5, more preferably less than 1.4. y and z can be adjusted to achieve a refractive index in the film of either composition between 1.80 and 2.03. Silicon nitride (preferably with the formula SiN_{1.3}) with a refractive index near 2.03 is most preferred.

The inorganic barrier coating layer 8 is direct deposited on the solar cell by a low temperature (<200° C., preferably <150° C., more preferably <100° C. wherein the temperature recited is the temperature at the surface where the deposition occurs) method. Preferably, the inorganic barrier is deposited on the surface of a solar cell via magnetron sputtering. Where a preferred silicon nitride layer is formed, the coatings of the present invention preferably are deposited using a reactive magnetron sputtering using a silicon target and a mixture of nitrogen and argon gas. The mole fraction of nitrogen in the gas feed is preferably more than 0.1, more preferably more than 0.2 and preferably less than 1.0, more preferably less than 0.5. For the examples described in this invention, the substrate temperature did not exceed about 100° C.

Surprisingly, the inventors discovered that when reactive sputtering was used to form a silicon nitride barrier on an inorganic oxide top layer of a PV cell a unique and unexpected interstitial layer between the top clear conductive oxide photovoltaic layer and the thicker, stoichiometric silicon nitride layer (FIG. 2). Based on the contrast difference shown in the SEM of FIG. 2, the interstitial layer appears to be of lower density compared to the bulk silicon nitride film. Characterization of the elemental composition of the interstitial layer shows that this layer is comprised of silicon oxynitride, with an oxygen content greater than that in the bulk silicon nitride film. Without wishing to be bound, it is postulated that the formation of this unique layer may be beneficial to the environmental barrier properties of the protective layer and the reduction/healing of lattice defects caused by excessive electron and ion bombardment during film formation. Again without wishing to be bound, it is believed the interstitial layer is a silicon oxy nitride layer.

Furthermore, the efficiency of the solar cell device immediately after deposition of the inorganic barrier coating should be at least 80% of the nominal efficiency of the device before coating. However, some recovery of nominal efficiency is typically observed in the next several days up to at least 95% efficiency. The inorganic barrier coatings may also be prepared by other low temperature vacuum methods known to those in the art including chemical vapor deposition (CVD), plasma-enhanced chemical vapor deposition (PECVD), atomic layer deposition (ALD) and others.

The barrier coatings useful in this invention exhibit optical transmittance ≧80% in the transmission wavelength range 400-1300 nm and preferably exhibit ≧85% transmission in the same range.

The inorganic coating should exhibit a water vapor transmission rate less than 1×10⁻² g/m²/day and preferably less than 5×10⁻⁴ g/m²/day. The inorganic coating can be applied as a single continuous layer or as multiple layers via sequential deposition or multiple passes during a single deposition. As noted above a two layer structure is surprisingly formed by a single reactive sputtering step of silicon nitride on an inorganic oxide.

The inorganic barrier layer can be provided on a single chalcogenide based cell or can be provided onto two or more such cells that are already electrically connected. In a solar cell module, individual solar cells often are arranged electrically in series. Tinned copper strips, called tabs, are soldered onto bus bars that are part of the topside grid structure on the solar cell. Series interconnection is achieved by soldering tabs from the front of one cell with the back of the adjacent cell, and continuing this interconnection for the desired length or number of solar cells for a given solar module design. Such interconnection is taught in Handbook of Photovoltaic Science and Engineering (A. Luque and S. Hegedus, Eds.) J. Wiley & Sons, Pub. West Sussex, 2003, pg. 291-292, also taught in the teachings of U.S. Pat. No. 4,241,493 (1980). If the individual cells are coated before interconnection known photolithography methods to form the exposed regions needed to make the electrical contacts.

Preferably, the photovoltaic article made by this method is flexible. By flexible is meant that the bending radius of the article can be reduced to 10 cm without cracking or delamination of the thin film materials.

### EXAMPLES

### Example 1

### CIGS Cells

CIGS-based cells are used which have a substrate of a Fe—Cr, body-centered cubic (BCC) stainless steel. The front side of the substrate is coated with a thin bilayer of chromium (Cr) and molybdenum (Mo) to form the back contact. Next, the absorber layer is fabricated by depositing a thin layer of NaF and then co-evaporating Cu, In, Ga, and Se (CIGS). The cadmium sulfide (CdS) buffer layer is deposited by chemical bath deposition (CBD). A thin, intrinsic ZnO (iZnO) serves as the window layer, which is then capped by an InSnO (ITO) transparent conductive oxide (TCO) layer. The device is completed by screen printing an Ag collection grid on the ITO. The initial cell efficiencies were on average 6.94±0.77%.

### Sputtering Method

Silicon nitride films are deposited from a pure Silicon target within an 80:20 Ar/N₂ gas mixture. The deposition rate is experimentally determined prior to sample generation for each deposition recipe. This technique ensures the film thickness deposited in the experimental runs are close to the desired value. Prior to the deposition, the system is pumped down to a base pressure of 5×10⁻⁷ torr. During the deposition, the system working pressure is held at 10 microns and chamber platen was in rotation. The target power is 1 kW RF, and the chamber reflected power ranged between 50 and 100 W. The target to substrate distance is 2 inches. For this system operating at the specified conditions, the nitride film deposition rate is 119 Å/min. The substrate temperature does not exceed 100° C. at any time during the deposition. The resulting sputtered silicon nitride film thickness is ˜5000 Å, measured using a Sloan Dektak II stylus profilometer.

### PECVD Method

Silicon nitride films are deposited in a working pressure of 425 mTorr. The gas mixture contained N₂, He, SiH₄, and NH₃ flowing at 2500, 500, 30, and 15 sccm, respectively. The plasma power was 400 W RF. For this system operating at the specified conditions, the nitride film deposition rate was 179 Å/min. The substrate temperature is held at 375° C. during the deposition. The resulting PECVD silicon nitride film thickness are ˜2000 Å, measured using a Sloan Dektak II stylus profilometer.

### Efficiency Measurement Method

The device efficiency is mathematically extracted from a current-voltage (I-V) characteristic curve that is measured before and after each step using a Class AAA Solar simulator. The I-V characteristic measurement apparatus and procedure meet the requirements specified in the IEC 60904 (parts 1-10) and 60891 standards. For each I-V measurement, electrical contact is established using a 5-μm-radius tungsten probe tip placed in contact with the collection grid bus bar and the Molybdenum coated back side was grounded thru an Au coated brass platen. During the experiment, it is found that some of the cells incurred some discoloration of the back side Molybdenum. This discoloration is gently removed using an IPA damp q-tip, exposing the underlying Molybdenum layer. This cleaning technique is used for all cells where this discoloration, perhaps corrosion, is visible. During the I-V characteristic measurement, the temperature of the platen and the device is maintained at 25° C. Prior to the measurement the Xe arc lamp is given 15 minutes to stabilize. Then, the lamp irradiance is set to AM1.5 1000 W/m² using a calibrated silicon reference device with BK-7 filter. The uncertainty in the efficiency measurement is ±4% of the tabulated value.

The normalized efficiency data for as-received devices before and after silicon nitride deposition are shown in Table 1. The samples that received silicon nitride by PECVD on average produced <6% of their average initial performance. The samples that received silicon nitride by sputtering on average produced ˜83% of their initial performance.

TABLE 1
Device performance before and after silicon nitride deposition.

| | Silicon | Normalized |
|---|---|---|
| | Nitride | Efficiency |
| | Encapsulation | After/Before |
| Sample ID | Technique | Encapsulation |
| 1 | Sputtered | 0.84 |
| 2 | Sputtered | 0.84 |
| 3 | Sputtered | 0.82 |
| 4 | PECVD | 0.01 |
| 5 | PECVD | 0.06 |
| 6 | PECVD | 0.10 |

### Example 2

Photovoltaic devices are prepared on 2″ square soda-lime glass substrates, 0.7 mm thick. A layer of molybdenum is sputter deposited at 200 W, 6e10⁻³ mbar on the glass substrate, to a final thickness of about 750-800 nm. CIGS absorber layer is deposited by a multi-stage metal co-evaporation process based on a three stage process practiced by National Renewable Energy Laboratory (NREL) (Repins, 2008). A cadmium sulfide buffer layer is deposited by chemical bath deposition (CBD) by dipping samples into a mixture of 33 mL 0.015 M CdSO_{4(aq)} and 42 mL 14.5 M NH₄OH_{(aq)} (concentrated NH₃) at 70° C. After 1 min 33 mL of 0.75 mL thiourea is added and the reaction is allowed to proceed for 7 min Samples are dried at 110° C. for 30 min The window layer, i-ZnO, is prepared by RF magnetron sputtering of a ZnO target at 60 W and 10 mtorr sputtering pressure (0.15% O₂ in Ar sputtering gas) to a final thickness of about 70 nm. Indium tin oxide (ITO) films are prepared using a custom RF magnetron sputter chamber from a 100 mm diameter, 5 mm thick ITO ceramic target (90 wt % In₂O₃, 10 wt % SnO₂) using gas flows of argon (14 sccm) and oxygen (2 sccm), controlled using mass flow controllers, to achieve a working gas pressure of 2.8 mTorr. The substrate temperature is held at 150° C. during deposition. The final film thickness is around 150 nm. Conductive grids are deposited on the surface of the devices by sequential evaporation of Ni and then Ag to a total thickness of about 1600 nm by E-beam evaporation on a Denton Explorer 14 system. Prior to evaporation, the chamber base pressure is reduced to <2e10⁻⁶ Torr. All depositions are carried out at 9.0 kV, while current values were 0.130 and 0.042 Amps for Ni and Ag, respectively. The deposition rates can be controlled in process using a Maxtek 260 quartz crystal deposition controller at 2.0 Å/s and 15.0 Å/s for Ni and Ag, respectively. Ni shots (99.9999%, obtained from International Advanced Materials) were evaporated from a 7 cc graphite crucible, while Ag pellets (99.9999%, Alfa Aesar) were evaporated from a 7 cc molybdenum crucible. The device performance is analyzed via I-V characterization as described in Example 1, then a layer of silicon nitride is deposited by radio-frequency (RF) magnetron reactive sputtering of a Si targets in an Ar/N₂ atmosphere. Depositions are conducted in an Anatech Hummer™ sputter system. The chamber is evacuated to a routinely achieved base pressure of <1×10⁻⁵ torr over a period of 2-3 h. Experiments are conducted with the platen in rotational mode. Circular targets (50 mm diameter, 6.4 mm thickness) of p-doped Si (99.999%). Following deposition, the device performance is evaluated, again by I-V characterization. Evaluation of 15 devices reveals that the mean device performance is 97% relative to the initial data prior to silicon nitride encapsulation.

### Example 3

CIGS-based devices, with and without nitride encapsulation made substantially as set forth in Example 1, are subjected to damp-heat, 85° C./85% RH, environmental weathering conditions as specified in IEC standard 61646. During the exposure, the cells are positioned vertically on a stainless steel fixture situated above a pool of DI water within a lab oven held at 85±5° C. To mitigate premature failure due to moisture ingress from the device edge, the devices are clamped in a metal or glass based package—we refer to this as the “packaged device”. Furthermore, a layer of silicone grease is applied to the edge of each device to reduce the likelihood of a cell experiencing premature failure due to moisture-ingress at the device edge. Periodically during the experiment the cells are removed from the test environment, and their package, and their I-V characteristic is measured. Prior to collecting the I-V characteristic measurement, the samples rest in a dry nitrogen purged box for at least 12 hrs. Then, just before collecting the I-V characteristic measurement, the samples are light soaked for at least 5 minutes using the SpectraNova solar simulator. Immediately following this measurement the devices are placed back into their package, clamped, and returned to the damp-heat environment for the next test period. This process is repeated for each time period.

The results of the exposure are tabulated in Table 2 and Table 3. For reference, the baseline performance of unencapsulated devices exposed to damp-heat conditions is also presented. The encapsulated device survived ˜1000 hrs in damp-heat conditions before losing >15% of its initial performance. For comparison, the unencapsulated as-received devices lose >15% performance after 100 hrs exposure to damp-heat conditions. Further exposure to damp-heat resulted in accelerated failure rate that lead to device failure. Interestingly, at approximately the same time that this increased failure rate was measured, the device began to curl or flex. Upon closer examination, physical defects and cracks were observed in the silicon nitride layer. Without wishing to be bound it is postulated that these defects were, incurred by handling and that these defects in the silicon nitride layer provided a pathway for moisture ingress, thereby resulting in the catastrophic failure.

TABLE 2
Normalized efficiency of sputtered silicon nitride encapsulated
device at different stages of exposure to damp-heat.

| | Time | Normalized |
|---|---|---|
| Step | (hrs) | Efficiency |
| As-received | 0 | 1.00 |
| After Nitride Encapsulation | 0 | 0.85 |
| After 168 hrs damp-heat | 168 | 1.03 |
| After 336 hrs damp-heat | 336 | 1.03 |
| After 504 hrs damp-heat | 504 | 0.99 |
| After 672 hrs damp-heat | 672 | 0.98 |
| After 840 hrs damp-heat | 840 | 0.87 |
| After 980 hrs damp-heat | 980 | 0.89 |
| After 1148 hrs damp-heat | 1148 | 0.80 |
| After 1316 hrs damp-heat | 1316 | 0.82 |
| After 1484 hrs damp-heat | 1484 | 0.80 |
| After 1500 hrs damp-heat | 1500 | 0.72 |
| After 1668 hrs damp-heat | 1668 | 0.44 |
| After 1836 hrs damp-heat | 1836 | 0.19 |
| After 2004 hrs damp-heat | 2004 | 0.00 |

TABLE 3
Normalized efficiency of unencapsulated devices at
different stages of exposure to damp-heat.

| | Time | Normalized |
|---|---|---|
| Step | (hrs) | Efficiency |
| As-received | 0 | 1.00 |
| After 48 hrs damp-heat | 48 | 0.96 |
| After 96 hrs damp-heat | 96 | 0.91 |
| After 157 hrs damp-heat | 157 | 0.79 |
| After 205 hrs damp-heat | 205 | 0.66 |
| After 236 hrs damp-heat | 236 | 0.56 |
| After 442 hrs damp-heat | 442 | 0.08 |
| After 646 hrs damp-heat | 646 | 0.006 |
| After 913 hrs damp-heat | 913 | 0.0002 |

### Example 4

Determination of water vapor transmission rate (WVTR) for silicon nitride films. Silicon nitride films are deposited onto Al-coated glass substrates by reactive RF sputtering from a silicon target in a 50/50 Ar/N₂ atmosphere. The sputter system consists of a 300 W, 13.56 MHz RF power supply and a 50 mm planar magnetron sputter source. Circular targets (50 mm diameter, 6.4 mm thickness) of p-doped Si (99.999) are used as the source of silicon. Prior to silicon nitride deposition experiments, the chamber is evacuated to a routinely achieved base pressure of <1×10⁻⁵ over a period of at least 2 h using a combination of a rotary and turbo pump. Ultra-high purity argon and nitrogen gases (99.9999) are introduced into the chamber using mass flow controllers. Deposition is carried out with target power set at 140 W and a working pressure of 4 mtorr. No intentional substrate heating is applied.

WVTR data for barrier films on aluminum coated substrates are conducted in an All-American 25× electric steam sterilizer equipped with an excess pressure relief valve. Nanopure® water is used exclusively in the pressure vessel to avoid contamination. For each sample, the initial optical density is measured at several points equally distributed across the surface of the substrate. The samples are then placed vertically in a glass substrate holder and introduced into the pressure vessel for exposure. The temperature is set to 115° C. using an external temperature controller with over temperature control. The temperature reading does not exceed ±1° C. of the set point. At this temperature, the pressure inside the vessel is approximately 12 psi. The samples are exposed for the desired duration and then removed from the pressure vessel and the optical density is measured again. The samples are then re-introduced into the pressure vessel and the process was repeated. Optical density measurements are carried out using an XRite® 361T transmission densitometer using a 3 mm aperture. The WVTR is then calculated using the following formula:

$$WVTR ( g \cdot {m}^{- 2} \cdot {d}^{- 1} ) = \frac{\begin{matrix}\{ \frac{\begin{matrix}[ \begin{matrix}( ODi \times 15.09 + 2.01 nm ) - \\ ( {OD}_{f} \times 15.09 + 2.01 nm )\end{matrix} ] \\ ( 2.7 {e}^{- 6} g \cdot {m}^{- 3} ) ( 1 {e}^{- 9} m )\end{matrix}}{26.98 g \cdot {mol}^{- 1} ( Al )} \} \times \\ 1.5 \times 18.02 g \cdot {mol}^{- 1} ( {H}_{2} O )\end{matrix}}{t ( h ) \div 24 h \cdot {d}^{- 1}}$$

where ODᵢ is the initial average optical density of the sample, OD_{f} is the final optical density of the sample measured at time, t (in h). The abbreviations, g, m, d, represent grams, meters, and days, respectively.

Silicon nitride films prepared under the conditions described above typically exhibit calculated WVTR in the range 1×10⁻⁴ to 9×10⁻⁴ g/m²/day.

### Example 5

A film of thickness 128 nm of indium tin oxide is deposited on a glass substrate via RF magnetron sputtering using a tin-doped indium oxide target in an argon/oxygen atmosphere. Prior to deposition, the chamber is evacuated to a base pressure of 8×10⁻⁶ torr. During deposition, the target power is set to 180 W and gas flows of argon (14 sccm) and oxygen (2 sccm) are controlled using mass flow controllers to achieve a working gas pressure of 2.8 mtorr. The substrate temperature is held at 150° C. and the platen holding the substrate is in rotation. The rate of deposition is 130 Å/min Following deposition, the chamber is vented to atmosphere, and then the sample is then transferred to a second sputtering chamber for silicon nitride deposition. The silicon nitride is deposited via reactive sputtering using a B-doped silicon target and a 50:50 Ar:N₂ gas ratio. The pressure during deposition is controlled at 4.0 mtorr, the power is set at 140 W and the chamber platen was in rotation. The target to substrate distance is 75 mm The silicon nitride film deposition rate is 40 Å/min Prior to the deposition, the system is pumped down to a base pressure of 9×10⁻⁶ torr. The thickness of the silicon nitride film determined by transmission electron microscopy (FIG. 2) and spectroscopic ellipsometry to be 150 nm The refractive index determined by the latter technique was 1.97. Characterization of the elemental composition of the silicon nitride layer by energy dispersive X-ray spectroscopy (EDS) revealed that the average composition was approximately Si_{0.40}N_{0.57}O_{0.03}. EDS characterization of the interstitial layer shows that this layer is comprised of silicon oxynitride with an average composition of Si_{0.33}N_{0.48}O_{0.19}. The change in contrast of the silicon nitride layer near the ITO interface (FIG. 2) is indicative of a decrease in mass thickness (i.e. density) of the film near the interface.

The transmission electron microscope (TEM) and energy dispersive X-ray spectrometer (EDS) work is carried out using a JEOL 2010F field emission gun (FEG) TEM. The TEM is operated at an accelerating voltage 200 keV. Conventional TEM images are recorded using a Gatan multi-scan digital camera (Model Ultrascan 1000) with a CCD size of 2048 pixels×2048 pixels. The JEOL 2010F is also equipped with an Bruker AXS XFlash 4030 (EDS) detector with an energy resolution of 137 eV/channel (SN 1576). Spectroscopic ellipsometric measurements of silicon nitride films on silicon substrates are carried out over the wavelength range 380-900 nm using a Woollam α-SE™ rotating compensator spectroscopic ellipsometer. Measurements are collected at an angle of incidence of 70°. Data analysis is carried out using the Woollam CompleteEASE™ software package. Parameters for silicon nitride and silicon oxynitride thin films are derived from a standard transparent film model using a Cauchy dispersion equation to describe the index of refraction (n).

What is claimed is:

1. A method of forming a photovoltaic article comprising:
providing at least one chalcogenide based photovoltaic cell, and
reactive sputtering inorganic barrier layer on the photovoltaic cell.

2. The method of claim 1 wherein the inorganic barrier layer comprises a material having the formula SiO_{y}N_{z}, where y is less than 0.05 and z is greater than 1.1 and less than 1.4.

3. The method of claim 2 wherein the inorganic barrier layer is sputtered onto a transparent conductive oxide layer which is on a top surface of the photovoltaic cell and an interstitial layer is formed between the transparent conductive oxide and the inorganic barrier layer during the reactive sputtering step.

4. The method of claim 3 wherein the interstitial layer is a silicon oxynitride having a higher oxygen content than is found in the inorganic barrier layer.

5. The method of claim 1 wherein the chalcogenide based photovoltaic cell comprises in order a backside substrate, a back electrical connector, a chalcogenide absorber, a buffer, a transparent conductive oxide, and an electrical collection grid.

6. The method of claim 5 wherein the chalcogenide absorber is of the formula CuIn₍₁₋ₓ₎GaₓSe_{(2-y)}S_{y} where x is 0 to 1 and y is 0 to 2.

7. The method of claim 6 wherein the substrate is stainless steel, the back electrical connector is molybdenum, the buffer is cadmium sulfide, and the transparent conductive oxide is indium tin oxide or aluminum zinc oxide.

8. The method of claim 1 wherein the sputtering step comprises sputtering a silicon target in the presence of nitrogen and argon gases where the mole ratio of nitrogen:argon is from 1:9 to 5:1 and the deposition occurs at temperatures of less than 100° C.

9. The method of claim 1 wherein more than one chalcogenide cell is provided and the more than one cells are electrically connected prior to sputtering of the inorganic barrier.

10. The method of claim 1 wherein more than one chalcogenide cell is provided further comprising electrically connecting the more than one cells after sputtering of the inorganic barrier.

11. A method of forming a photovoltaic article comprising providing a chalcogenide based photovoltaic cell and direct depositing onto the cell at a deposition temperature of less than 200° C. an inorganic barrier to form a photovoltaic article that retains at least 85% of its initial efficiency after exposure for 85° C. and 85% relative humidity for a time of at least 1000 hours.

12. The method of claim 11 wherein the deposition temperature is less than 100° C.

13. The method of claim 11 wherein the deposition occurs via reactive sputtering.

14. The method of claim 11 wherein the chalcogenide based photovoltaic cell comprises in order a substrate, a back electrical connector, a chalcogenide absorber, a buffer, a transparent conductive oxide, and an electrical collection grid.

15. The method of claim 11 wherein the chalcogenide absorber is of the formula CuIn₍₁₋ₓ₎GaₓSe_{(2-y)}S_{y} where x is 0 to 1 and y is 0 to 2.

16. The method of any of claims 15 wherein the backside substrate is stainless steel, the back electrical connector is molybdenum, the buffer is cadmium sulfide, the transparent conductive oxide is indium tin oxide or aluminum zinc oxide.

17. The method of claim 11 wherein the inorganic barrier is silicon nitride.

18. The method of claim 11 wherein more than one chalcogenide cell is provided and the more than one cells are electrically connected prior to forming the inorganic barrier.

19. The method of claim 11 wherein more than one chalcogenide cell is provided further comprising electrically connecting the more than one cells after forming the inorganic barrier.

20. An article formed by the method of claim 1.

21. An article formed by the method of claim 11.
